(19) United States
(12) Patent Application Publication
(10) Pub. No.: US 2015/0022224 A1
(43) Pub. Date: Jan. 22, 2015

(54) TOUCH SENSING DEVICE AND A DETECTION METHOD

(71) Applicant: CANATU OY, Helsinki (FI)

(72) Inventors: Matti Hannu Ruusunen, Espoo (FI); Jan Von Pfaler, Helsinki (FI); Bjorn Friour Mikladal, Helsinki (FI); Bradley J. Aitchison, Helsinki (FI); David P. Brown, Helsinki (FI)

(21) Appl. No.: 14/376,742

(22) PCT Filed: Feb. 6, 2013
(86) PCT No.: PCT/FI2013/050129

§ 371 Date: Aug. 5, 2014

Related U.S. Application Data
(60) Provisional application No. 61/595,309, filed on Feb. 6, 2012.

(51) Int. Cl. G01B 7/14; G01B 7/00; G01R 27/02; G01R 27/26; G06F 3/044; G01V 3/00

(52) U.S. Cl. CPC G01B 7/14; G06F 3/044; G01V 3/00; G01R 27/02; G01R 27/2611; G01R 27/2605; G01B 7/003; G06F 2203/04104; G06F 2203/04112; G06F 2203/04102; G01B 2210/58
USPC 324/691

(57) ABSTRACT

A touch sensor having a touch sensitive film, a signal filter, electrical circuitry and a processing unit. The film is capable of capacitive or inductive coupling to an external object when a touch is made by the object. The signal filter is formed by the resistance of the film and the capacitive or inductive coupling to the external object, and the filter has properties affected by location of the touch and/or capacitance or inductance of the touch. The electrical circuitry is coupled to the touch sensitive film and configured to supply excitation, amplitude and wave form into the signal filter and to receive response signals from the signal filter. The processing unit is configured to detect the presence or proximity of a touch, the location of said touch, the capacitance and/or inductance of said touch by processing response signals and thereby measuring changes in the properties of the signal filter.

### FIELD OF THE INVENTION

The present invention relates to touch sensing devices, more particularly to touch sensing devices having touch sensitive films, and to a method of detecting a touch and detecting its location.

### BACKGROUND OF THE INVENTION

User interfaces for different kinds of electrical apparatuses are nowadays more and more often made with different types of touch sensing devices based on touch sensitive films instead of conventional mechanical buttons. Well known examples include different kinds of touch pads and touch screens in mobile phones, portable computers and similar devices. In addition to the sophisticated and even luxurious user experience achievable, touch sensing devices based on touch sensitive films also provide a superior freedom to the designers continuously trying to find functionally more versatile, smaller, cheaper, lighter, and also visually more attractive devices.

A key element in such touch sensing devices is a touch sensitive film comprising one or more conductive layers configured to serve as one or more sensing electrodes. The general operating principle of this kind of film is that the touch of a user by, e.g. a fingertip or some particular pointer device is detected by means of measuring circuitry to which the touch sensitive film is connected. The actual measuring principle can be e.g. resistive or capacitive, the latter one being nowadays usually considered the most advanced alternative providing the best performance in the most demanding applications.

Capacitive touch sensing is based on the principle that a touch on a touch sensitive film means, from electrical point of view, coupling an external capacitance to the measurement circuitry to which the touch sensitive film is connected. With sufficiently high sensitivity of the touch sensitive film, even no direct contact on the touch sensitive film is necessitated but a capacitive coupling can be achieved by only bringing a suitable object to the proximity of the touch sensitive film. The capacitive coupling is detected in the signals of the measurement circuitry. In a so called projected capacitive method, the measurement circuitry includes drive electrodes and sense electrodes used for supplying the signal and sensing the capacitive coupling, respectively. This circuitry is also arranged to rapidly scan over the sensing electrodes sequentially so that coupling between each supplying/measuring electrode pair is measured.

Common for the known touch sensitive films in the projected capacitive method is that the need to properly determine the location of the touch necessitates a high number of separate sensing electrodes in the conductive layers. In other words, the conductive layers are patterned into a network of separate sensing electrodes. The more accurate resolution is desired, the more complex sensing electrode configuration is needed. One particularly challenging issue is the detection of multiple simultaneous touches which, on the other hand, often is one of the most desired properties of the state-of-the-art touch sensing devices. Complex sensing electrode configurations and a high number of single sensing electrode elements complicates the manufacturing process as well as the measurement electronics of the touch sensing device.

In touch screens, in addition to the touch sensing capability, the touch sensitive film must be optically transparent to enable use of the film in or on top of a display of an electronic device, i.e. to enable the display of the device to be seen through the touch sensitive film. Moreover, transparency is also very important from the touch sensitive film visibility point of view. Visibility of the touch sensitive film to the user of e.g. an LCD (Liquid Crystal Display), an OLED (Organic Light Emitting Diode) display, or an e-paper (electronic paper) display seriously deteriorates the user experience. So far, transparent conductive oxides like ITO (Indium Tin Oxide) have formed the most common group of the conductive layer materials in touch sensitive films. However, from the visibility point of view, they are far from an ideal solution. The high refractive index of e.g. ITO makes the patterned sensing electrodes visible. The problem is emphasized as the sensing electrode patterning becomes more complicated.

One promising new approach in touch sensitive films is found in layers formed of or comprising networked nanostructures. In addition to a suitable conductivity performance, a layer consisting of networks of e.g. carbon nanotubes (CNT), or carbon NANOBUDs having fullerene or fullerene-like molecules covalently bonded to the side of a tubular carbon molecule (NANOBUD® is a registered trade mark of Canatu Oy), can be made less visible to a human eye than e.g. transparent conductive oxides like ITO, ATO or FTO. Besides, as is well known, nanostructure-based layers can possess flexibility, mechanical strength and stability superior in comparison with e.g. transparent conductive oxides.

One nanostructure-based solution is reported in US 2009/0085894 A1. According to the description thereof, the nanostructures can be e.g. different types of carbon nanotubes, graphene flakes, or nanowires. Doping of the film is mentioned as a means for increasing the electrical conductivity thereof. Two-layer configurations based on mutual capacitance and single-layer self-capacitance approaches are discussed there. Multiple touch detection is stated to be possible by means of the films disclosed. However, the common problem of very complex electrode and measurement circuitry configurations is not solved in this document.

Another prior art solution is suggested in WO 2011/107666 A1. It discloses a touch sensing device having a touch sensitive film, e.g. made of a network of nanostructures, the film having sheet resistance above 3.0 kΩ. While the problem of complex circuitry is addressed in that invention, it still only suggests operating with high resistance films and at limited frequency ranges.

There is a need to provide a versatile touch sensing device that has a simple sensing electrode configuration, preferably enables single-layer capacitive operation principle, can operate at a wide range of conductive film resistances, enables signal frequency tuning for better noise control, and allows using a wide variety of sensing algorithms.

### PURPOSE OF THE INVENTION

The purpose of the present invention is to provide novel solutions that have at least some or all the above-mentioned advantages.

### SUMMARY OF THE INVENTION

According to a first aspect of the invention there is provided a touch sensing device, comprising: a touch sensitive film comprising conductive material having a resistance, the film being capable of capacitive or inductive coupling to an external object when a touch is made by said external object; a signal filter formed at least by the resistance of the touch sensitive film and the capacitive or inductive coupling to the external object, the signal filter having properties that are affected at least by the location of the touch, the capacitance or inductance of the touch or by a combination of said properties of the touch; electrical circuitry resistively or wirelessly coupled to the touch sensitive film at one or more locations, the electrical circuitry being configured to supply one or more excitation signals having at least one frequency into the signal filter and to receive one or more response signals from the signal filter; and a processing unit resistively or wirelessly coupled to the electrical circuitry, wherein the processing unit is configured to detect the presence or proximity of a touch by the external object, the location of said touch, the capacitance or inductance of said touch, or a combination thereof by processing one or more response signals and thereby measuring changes in the properties of the signal filter.

A touch sensitive film means, in general, a film which can be used as a touch sensitive element in a touch sensing device. A touch sensing device is to be understood here broadly to cover all user interface devices operated by touching the device by an external object, as well as other types of devices for detecting the presence, proximity and location of such objects.

The touch sensitive film of the present invention is capable of capacitive or inductive coupling to an external object, which means that a touch by an external object causes changes in the filtering properties of the film.

The word “touch” and derivatives thereof are used in the context of the present invention in a broad sense covering not only a direct mechanical or physical contact between the fingertip, stylus, or some other pointer or object and the touch sensitive film, but also situations where such an object is in the proximity of the touch sensitive film so that the object generates sufficient capacitive or inductive coupling between the touch sensitive film and the ambient, or between different points of the touch sensitive film. In this sense, the touch sensitive film of the present invention can also be used as a proximity sensor.

By “conductive material” is meant here any material capable of allowing flow of electric charge in the material, irrespective of the conductivity mechanism or conductivity type of the material. Thus, conductive material covers here, for instance, also semiconductive or semiconducting materials. There can be one or more layers of conductive material in a touch sensitive film.

In addition to the conductive material, the touch sensing device can also comprise other layers of material and structures needed to implement an entire working touch sensitive element. For example, there can be one or more layers for mechanical protection of the film. Moreover, there can be also one or more layers for refractive index or color matching, and/or one or more coatings, for instance, for anti-scratch, decorative, water repellant, self-cleaning, or other purposes. Besides the layered elements, the touch sensitive film can also comprise three-dimensionally organized structures, e.g. contact structures extending through the touch sensitive film or a portion thereof.

A signal filter is formed at least by the touch sensitive film resistance and the capacitive or inductive coupling to an external object. This signal filter can be e.g. a low-pass filter, a high-pass filter, a band-stop or band-pass filter. An example of a low-pass filter would be an RC (resistor-capacitor) series circuit across the input, with the output taken across the capacitor. In an exemplary embodiment of the present invention, the film resistance could represent R and the capacitive coupling created by the touch could represent C in the above low-pass filter.

By an “external object” is meant any capacitor or inductor or capacitive or inductive pointer, e.g. a human finger or a metal stylus, pointers having a capacitive element or a metallic coil for inductive coupling etc. For example, a stylus with a coil can be either passive (no current is actively applied to the coil) or active (an AC or DC current is applied to the coil). A stylus with an active coil is generally used to improve the accuracy, response time, or transparency of the touch.

Forming of a signal filter by the resistance of the touch sensitive film and the coupling to the external object is based on an observation by the inventors that such a filter changes its properties in response to a touch from an external object, and that this change can be measured to detect the touch, its location and determine the capacitance or inductance of the touch with a very high precision.

The electrical circuitry according to this embodiment is resistively or wirelessly coupled to the touch sensitive film at one or more locations. The circuitry can comprise different types of contact electrodes, wirings and other forms of conductors, switches, and other elements needed to connect the touch sensitive film and the one or more conductive layers thereof to the rest of the touch sensing device. Resistive connection implies physical contact, while e.g. radio wave, inductive or capacitive coupling relates to wireless coupling. Examples of resistive coupling include but are not limited to soldering, clamps or other traditional techniques.

The electrical circuitry is configured to supply one or more excitation signals to the signal filter, and to receive one or more response signals from the filter. The electrical circuitry is connected to a processing unit, as described below. In an exemplary embodiment of the invention, the signals are sent to the filter and received from it by the processing unit via the electrical circuitry. The supplied one or more excitation signals have at least one frequency, amplitude and wave form. This means that each signal may vary in frequency, amplitude or wave form or have a constant frequency, amplitude and wave form, and, in case of multiple signals, they may have equal or different frequencies, amplitudes and wave forms. In practice, electrical circuitry together with the processing unit may be partly or fully integrated to a single chip.

An excitation signal can be any electrical signal, e.g. a pulsed, rise and fall time limited or oscillating voltage or current, supplied to the signal filter of the touch sensitive film via the circuitry and providing conditions suitable for monitoring the changes a touch induces in the filter properties. The excitation signal could also be called, for example, a drive signal or a stimulation signal. Typical examples are AC current and/or voltage. A response signal is correspondingly any measured electrical signal received from the signal filter by using the circuitry and allowing detection of a touch on the basis of changes the touch causes to the filter properties and detectable by this signal.

In an embodiment, the processing unit is resistively or wirelessly coupled to the electrical circuitry. The processing unit is configured to detect the presence or proximity of a touch by the external object, the location of said touch, the capacitance or inductance of said touch, or a combination thereof by processing one or more response signals and thereby measuring changes in the properties of the signal filter.

The processing unit can comprise a processor, a signal or pulse generator, a signal comparer, an interpretation unit, and other hardware and electronics as well as software tools necessary to process the response signals.

The touch sensing device is capable of operation in a single-layer mode utilizing a touch sensitive film having one single conductive layer only. This is an advantageous simplification in comparison with most prior art capacitive touch sensitive films utilizing a two-layer approach using different conductive layers for the excitation and the response signals.

According to an embodiment, the electrical circuitry is configured to receive one or more response signals from the signal filter. In this embodiment, the processing unit is configured to detect the presence or proximity of a touch by the external object, the location of said touch, the capacitance or inductance of said touch, or a combination thereof, by comparing said response signals to each other and thereby measuring changes in the properties of the signal filter. In an alternative embodiment, the processing unit is configured to compare the response signals to the excitation signals to measure changes in the properties of the signal filter.

In an embodiment, an alternating current or voltage is provided as an excitation signal to the signal filter at one point thereof and alternating voltage or current as a response signal is measured at another point of the filter.

In an embodiment, the signal filter is further formed by at least one external component. This at least one external component is a part of the touch sensing device of the above embodiments and it is resistively or wirelessly coupled to the processing unit via the electrical circuitry. The external component can be a resistor, constant current source, capacitor or inductor or a combination thereof. This external component can be integrated into other units in the device.

In an embodiment, an alternating current or voltage is provided as an excitation signal to the signal filter through an external component at one point thereof and alternating voltage or current as a response signal is measured at the same point of the filter.

According to an embodiment, the properties of the signal filter are further affected by the distance between said external object and the sensing film, the capacitance or inductance of the external object, physical properties of said external object, the resistance of the film, the existence, thickness or dielectric constant of a dielectric or insulating layer between the sensitive film material and the external object, or by a combination thereof.

The physical properties of the external object include e.g. its geometry, material, orientation and configuration.

According to an embodiment, the electrical circuitry comprises one or more electrodes, and wherein at least one of the electrodes is configured to supply said excitation signal into the signal filter, and at least one of the electrodes is configured to receive said electrical response signal from the signal filter. The number of the electrodes may vary depending on the structure.

In one preferred embodiment, the measured properties of the signal filter include amplitude response, phase response, voltage response, current response or a combination thereof. These properties can be affected by the presence or proximity of a touch, its location and its capacitance or inductance.

According to a preferred embodiment of the present invention, the processing unit is further configured to select one or more properties to be measured based on at least one pre-determined frequency, amplitude and wave form of the excitation signal so as to maximize the signal to noise ratio and/or improve the accuracy of the device at the pre-determined frequency, amplitude and wave form.

An optimal excitation frequency depends on many factors. Noise may increase at lower frequencies. On the other hand, antenna effects disturbing the touch detection becomes a problem at very high frequencies. Antenna effects mean that different parts of the measurement circuitry act like antennas tending to couple disturbance signals between the circuitry and the ambient. There usually is an optimal frequency range between a lower and an upper cut-off frequency. This range depends, for example, on the resistance of the conductive material in the touch sensitive film, the thickness and dielectric constant of any coating layer over the film, the capacitance or inductance of the external object, the frequencies of the surrounding electronics and the material of the substrate on which the conductive film lies. For example, with a sufficient high frequency, a PET substrate becomes conductive, thereby interfering with the excitation and response signals. Therefore, the ability to choose the operating frequency range, to actively tune the frequency based on those factors affecting the optimal frequency and to adjust the device accordingly (i.e. by choosing the filter property to be measured or the particular excitation frequency within the operating range) is provided.

According to an embodiment, the touch sensitive film of the touch sensing device extends as a continuous structure in a plane. This means that the touch sensitive film extends, for example, as solid, non-interrupted, and non-patterned structure substantially over the entire sensing area of the touch sensing device, though, as in the case of, for instance, HARM networks, the structure is not strictly continuous at the nano or micro scale. This structure is also optionally homogenous. This feature not only minimizes the visibility of the conductive layer but also simplifies the manufacturing thereof when no patterning of the layer is needed. It also simplifies the electronics of a touch sensing device having a touch sensitive film according to this embodiment.

The good sensitivity and touch location resolution performance of the touch sensitive film enable use of such a non-patterned conductive layer in a single-layer operation mode. Operation in a single-layer mode means that only one single conductive layer is used in touch sensing measurements. Multi-touch detection capability is also available in a non-patterned single-layer operation mode. Single-layer capability as such also allows producing the entire touch sensitive film as a rather thin structure.

In one embodiment, the touch sensitive film comprises: a single stripe or two or more parallel stripes made of the conductive material and extending over the touch sensitive film in one direction and areas between said stripes comprising non-conducting material, wherein the electrical circuitry is resistively or wirelessly coupled to each of the stripes, and the processing unit is further configured to detect the presence, proximity and location of the touch along each stripe.

The electrodes of the electrical circuitry are coupled to each stripe to supply and receive signals for measurement. The touch location has to be determined only in one dimension, and it is possible to use only one electrode per stripe to do so.

In one embodiment, the touch sensitive film is formed as a flexible structure so as to allow bending thereof. A “flexible” structure means here a structure allowing bending of the film, preferably repeatedly, in at least one direction. In an embodiment, the touch sensitive film is flexible in at least two directions simultaneously.

Instead of or in addition to the flexibility, the touch sensitive film can also be formed as a deformable structure so as to allow deforming thereof, e.g. by using thermoforming, along or over a three dimensional surface.

Flexibility and/or deformability of the touch sensitive film in combination with the measurement features open entirely novel possibilities to implement touch sensing devices. For example, a touch sensitive film serving as the user interface of a mobile device can be bent or formed to extend to the device edges so that the touch sensitive film can cover even the entire surface of the device. In a touch sensitive film covering different surfaces of a three-dimensional device, there can be several touch sensing regions for different purposes. One sensing region can cover the area of a display to form a touch screen. Other sensing regions e.g. at the sides of the device can be configured to serve as touch sensitive element replacing the conventional mechanical buttons, e.g. the power button or volume or brightness sliders or dials.

A good choice for flexible and/or deformable touch sensitive films is a conductive layer comprising one or more HARMS (High Aspect Ratio Molecular Structure) networks, as described in more detail below. HARM structures and the networks thereof are inherently flexible, thus enabling making the touch sensitive film bendable and/or deformable.

Preferably, the touch sensitive film is optically transparent, thus enabling use of the touch sensitive film e.g. as part of a touch screen. Optical transparency of the touch sensitive film means here that at least 10%, preferably at least 90% of the incident radiation from a direction substantially perpendicular to the plane of the film, at the frequency/wavelength range relevant in the application at issue, is transmitted through the film. In most touch sensing applications, this frequency/wavelength range is that of visible light.

For the optical transparency, the key is the conductive material of a touch sensitive film. The requirement of simultaneous electrical conductivity and optical transparency limits the number of possible materials. In this sense, HARMS networks form a good basis for an optically transparent touch sensitive film because the HARMS networks can provide a transparency superior to that of the transparent conductive oxides, for example.

In one embodiment, the touch sensitive film comprises a High Aspect Ratio Molecular Structure (HARMS) network, a conductive polymer, graphene or a ceramic, grids of metal such as silver or gold, or metal oxide. By HARMS or HARM structures is meant here electrically conductive structures with characteristic dimensions in nanometer scale, i.e. dimensions less than or equal to about 100 nanometers. Examples of these structures include carbon nanotubes (CNTs), carbon NANOBUDs (CNBs), metal nanowires, and carbon nanoribbons. In a HARMS network a large number of these kinds of single structures, e.g. CNTs, are interconnected with each other. In other words, at a nanometer scale, the HARM-structures do not form a truly continuous material, such as, e.g., the conductive polymers or Transparent Conductive Oxides, but rather a network of electrically interconnected molecules. However, as considered at a macroscopic scale, a HARMS network forms a solid, monolithic material. HARMS networks can be produced in the form of a thin layer.

The advantages achievable by means of the HARMS network(s) in the sensitive film include excellent mechanical durability and high optical transmittance useful in applications requiring optically transparent touch sensitive films, but also very flexibly adjustable electrical properties. To maximize these advantages, the conductive material can substantially consist of one or more HARMS networks.

The resistivity performance of a HARMS network is dependent on the density (thickness) of the layer and, to some extent, also on the HARMS structural details like the length, thickness, or crystal orientation of the structures, the diameter of nanostructure bundles etc. These properties can be manipulated by proper selection of the HARMS manufacturing process and the parameters thereof. Suitable processes to produce conductive layers comprising carbon nanostructure networks are described e.g. in WO 2005/085130 A2 and WO 2007/101906 A1 by Canatu Oy.

In one embodiment of the touch sensing device according to the present invention, the touch sensing device comprises also serves as a haptic interface film. In other words, the device further comprises means for providing a haptic feedback, preferably via the sensitive film, in response to a touch. Providing the haptic feedback via the sensitive film means that, instead of the conventional approach based on separate actuators attached to the touch sensitive film for generating vibration of the touch sensitive film, the sensitive film is used as a part of the means for generating the haptic feedback. There are various possibilities for this. A haptic effect can be achieved by generating suitable electromagnetic field(s) by means of the sensitive film. The skin of the user touching the touch sensitive film senses these fields as different sensations. This kind of approach can be called capacitive haptic feedback system. On the other hand, the sensitive film can alternatively be used, for instance, as a part of an electroactive polymer (artificial muscle) based haptic interface, wherein the sensitive film forms one layer of the interface.

One possibility to perform the both functions, i.e. the touch detection and haptic feedback, is that the sensitive film is alternately coupled to a touch sensing circuitry and to means for producing the signals for haptic feedback so that once a touch is detected during a first time period, a haptic feedback is then provided at a second time period following the first one. The first and second time periods can be adjusted to be so short that the user experiences the device operating continuously.

One or more touch sensitive films can alternatively be used, for instance, in conjunction with a fluidics based haptic interface (as is under commercialization by Tactus Technologies), wherein the touch sensitive film is integrated with the flexible outer haptic film which changes shape due to the pumping of a fluid into flexible reservoirs. One or more touch sensitive films can be on the inner and/or outer surfaces of the flexible outer haptic film. In this case, the touch sensitive film can be continuously coupled to the touch sensing circuitry.

In one embodiment of the touch sensing device according to the present invention, the touch sensing film also serves as a deformation detecting film. This means that the device incorporates means for e.g. sensing bending, twisting and/or stretching of the sensing film. This can be done by measuring changes in the resistance between nodes or by changes in the signal filter properties simultaneously with the touch sensing according to the invention. As the signal filtering properties of the system are a function of the resistivity of the film and, at least for certain materials, including but not limited to HARMs and conductive polymers and in particular nanotubes and NANOBUDs and more specifically, carbon nanotubes and NANOBUDs, the signal filter properties can change if the film is e.g. stretched, compressed or otherwise deformed. By interpreting this change in either the resistivity or signal filter properties, the present invention can detect, for instance, elongation or compression between nodes connected to the sensor film. Thus, for example, sensing of elongation between two sets of nodes at opposite corners indicates bending, while sensing elongation in one direction and compression in the other indicates twisting. In some configurations, one or more nodes can be used to sense in multiple directions. Alternative configurations are possible according to the invention.

For certain deformable external objects, the capacitance or inductance changes with the force applied to the touch sensitive film and thus the determined capacitance or inductance can be used as a proxy for force. The force means e.g. a force which a user applies to the device when performing a touch. A human finger, for instance, deforms upon the application of a force resulting in increased area in proximity to the sensor film. This will cause the capacitance to change accordingly. Alternatively, if an inductive external object is used, and the user deforms, for instance, a coil of the external object or changes the distance from the coil to the surface (e.g. via a spring), inductance changes accordingly and force can be measured as well.

The touch sensing device of the present invention can be implemented as a standard or customized stand-alone module or as an non-separable unit integrated as a part of some larger device, e.g. a mobile phone, portable or tablet computer, e-reader, electronic navigator, gaming console, refrigerator, blender, dishwasher, washing machine, coffee machine, stove, oven or other white goods surface, car dashboard or steering wheel, etc.

According to one embodiment of the present invention, the wireless coupling between parts of the device is one of the following: coupling by radio waves, coupling through magnetic fields, inductive or capacitive coupling.

By “the wireless coupling between parts of the device” is meant a wireless coupling between any device elements described above.

The setup may require supplemental electronics that handle the creation, sending and receiving of the data and the AC current that creates either electrostatic or electrodynamic induction between electrodes that are located on both the main device and the touch sensing module. These two devices may be wirelessly coupled together by one or more of the following methods:
Electromagnetic induction (Inductive coupling, electrodynamic induction), where the data and power transmission is induced by current from a magnetic field between opposing coils.
Magnetic resonance is near field electromagnetic inductive coupling through magnetic fields.
Radio waves (e.g. RFID technology), wherein the power is generated from the radio waves received by the antenna, and the data transmission substantially changes the radiated field load.
Capacitive coupling (or electrostatic induction), wherein the energy and data are transferred from opposing planes of electrodes.

Touch sensors can be fully or partly integrated to the application devices either by wires, directly soldered or via connectors. This is sufficient in fixed installations where the sensors typically are positioned in areas that are not required to be open apart. E.g. in portable devices they are typically found in touch display applications, wherein the display is actually beneath the touch sensing film and the screen itself is permanently attached to the device. If a touch sensing device is located on a removable part of a device, then it would typically require a connector by which it could connect to the device once it is attached to it. This method is functional but it may not be suitable in certain applications. Moreover, even if a touch component is intended to be permanently affixed to a device, there are manufacturing costs and design limitations associated with connecting the component via solder or connectors.

In one embodiment of the present invention, a touch sensing device is provided. It comprises a touch sensing module comprising a touch sensitive film, electrical circuitry configured to supply one or more excitation signals to the touch sensing module and to receive one or more response signals from the touch sensitive module. In accordance with this embodiment, the electrical circuitry is coupled to the touch sensing module wirelessly.

In an embodiment, a 2- and 3-dimensional touch sensor devices are provided to applications whose enclosure cover has to be removed, for example to maintain and change the serviceable parts inside. It is also a robust method to provide data entry method to devices requiring unbroken encapsulation for, for example, wet, explosive or otherwise hazardous environments or where direct connection, as with interconnecting wires, is otherwise impossible, costly or highly inconvenient.

In an embodiment, no physical connector for power and data transmission that is susceptible to dirt, wear and tear or breakage. With no connector there are fewer parts susceptible to contamination, chemical or physical degradation or mechanical damage thus increasing the reliability of the device.

A direct physical contact can be avoided which, if not secured firmly, may have an unintentional disconnection and thus lead to data or power loss. It may function as a remote control device to fixed installations that takes the power from the installation and works as an ad-hoc touch sensor or generic data input output device.

By keeping the touch sensor functionalities in a module and separating it from the main device, they become different serviceable parts that can be produced separately and combined together only at the final assembly. An electrode can be implemented cost-efficiently as a metal area or printed wire on printed circuit board.

According to an embodiment, the touch sensor module and the main device may be physically attached to each other but the power or data or both are transmitted wirelessly between them. In practice, the sensor, excitation and sensing electronics together with the data processing unit so that the whole unit is an independent peripheral plug-in.

According to a second aspect of the present invention there is provided a method for detecting the presence, proximity, location, inductance, capacitance or a combination of these features of an external object with a touch sensing device, the method comprising: supplying one or more electrical excitation signals having at least one frequency, amplitude and wave form into a signal filter formed at least by a resistance of a touch sensitive film in the touch sensing device and a capacitive or inductive coupling of said film with the external object, receiving one or more response signals from the signal filter, and detecting the presence of a touch by the external object, or the location of said touch by processing said one or more response signals and thereby measuring changes in properties of the signal filter.

Touch detection sensitivity and touch location resolution of a touch sensing device do not depend on the properties of signal filter and the processing means performance only. Naturally it is also a matter of, e.g., the contact electrode configuration. On the other hand, the touch location resolution of the touch sensitive film and a touch sensing device utilizing it depend also on the number of the contact locations and the placing of them with respect to each other and the film. These are critical issues particularly in a single-layer approach with a non-patterned conductive layer. Typically, the earlier known devices of this type, described e.g. in U.S. Pat. No. 7,477,242 B2 and US 2008/0048996 A1, rely on a rectangular-shaped conductive layer and four contact electrodes at the corners thereof. However, this configuration necessitates very complex signal processing, and the accuracy of this device is quite low. It is particularly hard to provide a flexible structure according to that solution. Also, the multi-touch capability can be very challenging to achieve with that kind of approach. These difficulties are mitigated or avoided in the present invention.

Below, the present invention is illustrated on the basis of examples with references to the accompanying drawings.

### BRIEF DESCRIPTION OF THE DRAWINGS

FIGS. 1a, 1b and 1c illustrate one possible configuration of a touch sensing device according to the present invention.

FIGS. 2a, 2b and 2c illustrate another possible configuration of a touch sensing device according to the present invention.

FIGS. 3a and 3b are an illustration of a two-dimensional unpatterned touch sensitive film according to an embodiment.

FIGS. 4a, 4b and 4c show an embodiment having deformation sensing capabilities.

FIG. 5 illustrates another embodiment in which a striped touch sensitive film is used.

FIG. 6 shows an embodiment having U- and C-shaped stripes in a grid.

FIGS. 7a and 7b are diagrams of compared received response signals from a touch sensing device according to the present invention.

FIGS. 8a, 8b and 8c are diagrams of received response signals compared to excitation signals.

### DETAILED DESCRIPTION OF THE INVENTION

An explanation of the invention follows based on the examples described below.

Capacitive or inductive coupling to an external object together with a resistive film compose an electronic signal filter. A touch sensitive film with sufficient electrical resistivity together with an external object having capacitance or inductance creates a low-pass RC filter due the resulting RC time constant of the system. The properties of this low-pass filter depend on the sheet resistance, as well as on location and capacitance or inductance of the external object.

In the typical operational mode, one or more oscillating signals or pulses are fed into the filter at one or more locations. In the touch sensitive film, the resistance between any two points on or at the edge of the touch surface is a function of their relative location and the geometry and sheet resistance of the sensor area. The capacitance or inductance in this system is a combination of parasitic capacitance or inductance of the system and the capacitance or inductance formed between the film and coupled external object. A change in the electronic filtering characteristics is substantial when, in addition to the film's resistivity, there is a load caused by one or more capacitively or inductively coupled touches present in the system. By measuring changes in the mentioned signal or pulse, the change in the electronic filter characteristics can be measured and thus the location of one or more touches can be deduced. By measuring e.g. the change in the current into the sensing film, the capacitance or inductance between the sensor and the external object can be calculated. Likewise, the signal changes per sensing node (the part of the electrical circuitry, connected to the touch sensitive film at a particular location) indicate changes in relative distance to the external object and, by comparing the differences between the response signal at the sensing nodes, together with knowledge of the total current consumption and absolute values at the sensor nodes, the relative position of the touch can be calculated by various algorithms. For instance, the amplitudes of the sampled pulses are in correlation to the touch position and can be used for determining the actual position.

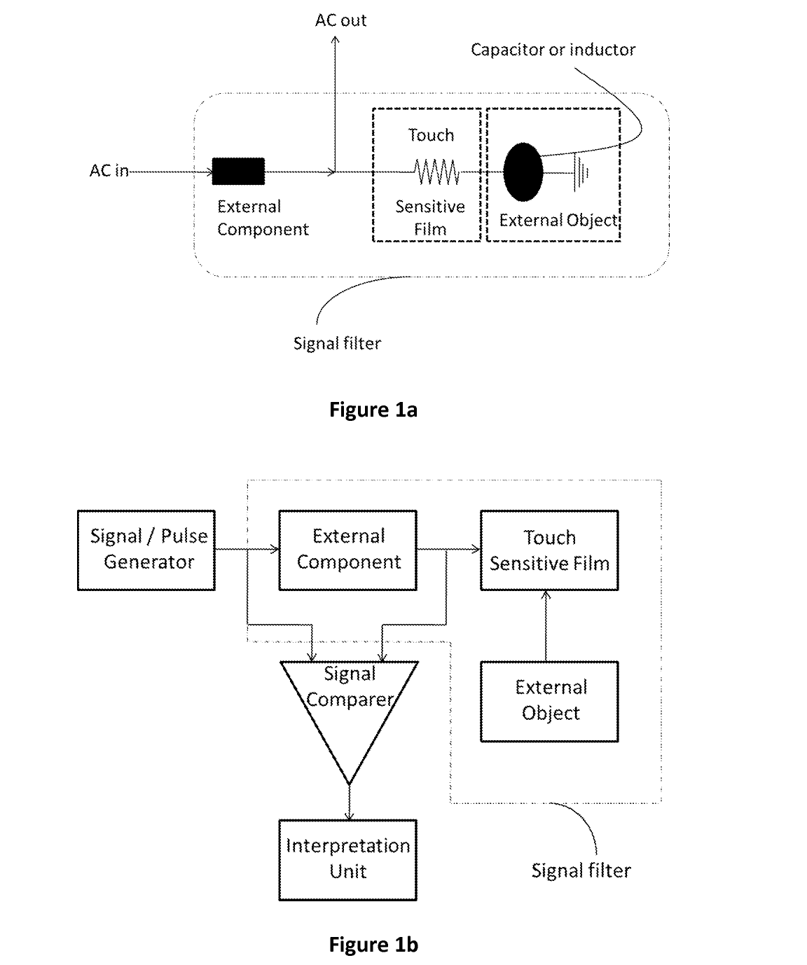

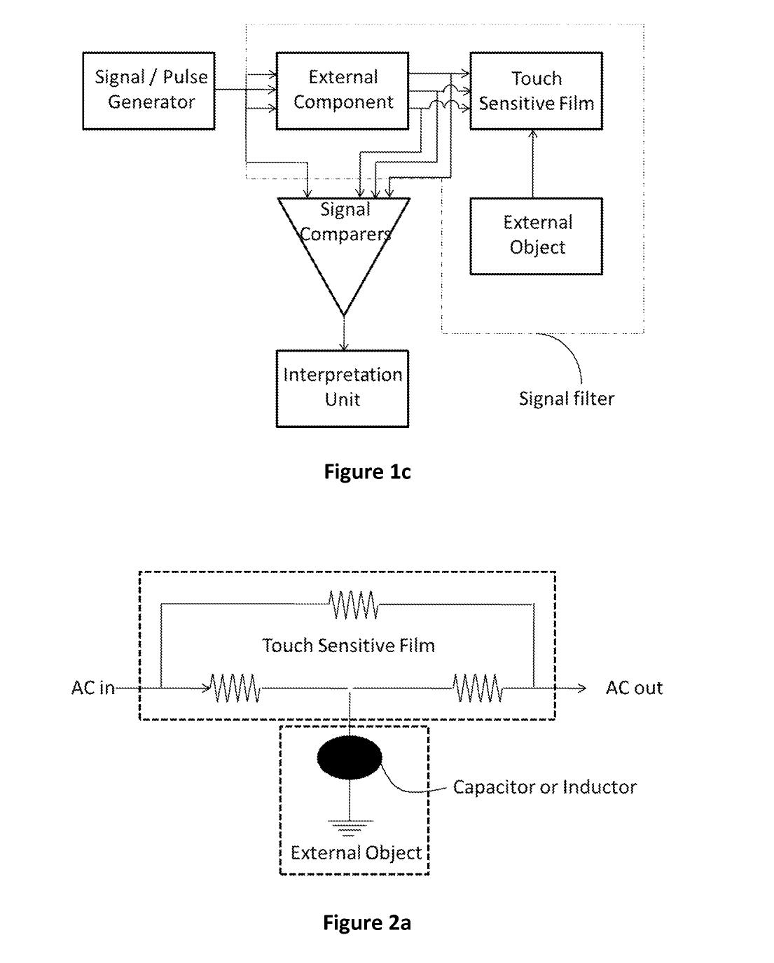

FIG. 1a shows an embodiment wherein a signal is supplied to a node and the effect of the low-pass filter is measured via the same node. The system consists of a touch sensitive film having a resistivity and an external object that capacitively or inductively couples to this touch sensing film. The signal or pulse is introduced at a point in the sensitive film, typically at an edge, though it may be introduced anywhere in the film. An external component such as a resistor, constant current source, capacitor or inductor or combination thereof, can be used to, for instance, increase the voltage linearity of the measurement, distribute the current or potential more evenly so as to avoid singularities in the system and allow current or voltage potential to be measured. The external component creates, together with the resistive film and external touch object, a low-pass filter. The signal couples to the load created by the touch film and the external object and, by changing the low-pass filter characteristics of the system, thus altering the signal. The altered signal is sampled (received) between the external component and the touch sensitive film. For measuring multi-touch of two or more external objects the measurement principle is similar to single touch situation with the distinction that instead of one there forms up to two or more parallel paths to the external object capacitance or inductance and the capacitive or inductive coupling increases. The sampled signal is different depending on the location and capacitance or inductance of the external object and the interaction of the signal with the low-pass filter formed by the touch film, the external component and the external object. Using multiple inputs/sensing nodes permits one to more exactly specify the location of the touch and the capacitance or inductance of the external object. In the embodiment, to specify x and y locations and the capacitance or inductance, 3 nodes, that can be used in various possible combinations as input and sensing nodes, are needed for each touch, thus, e.g., for 4 simultaneous touches, 12 input and sensing nodes are needed.

A more general configuration of the embodiment according to FIG. 1a is shown on a block diagram of FIG. 1b, and a specific embodiment where three signals or pulses are supplied via three external components to three points (nodes) on the touch film are illustrated on FIG. 1c. The sampled signals or pulses are then compared to the source signal or pulse or to other sampled signals or pulses to determine the location and/or capacitance or inductance of the external object.

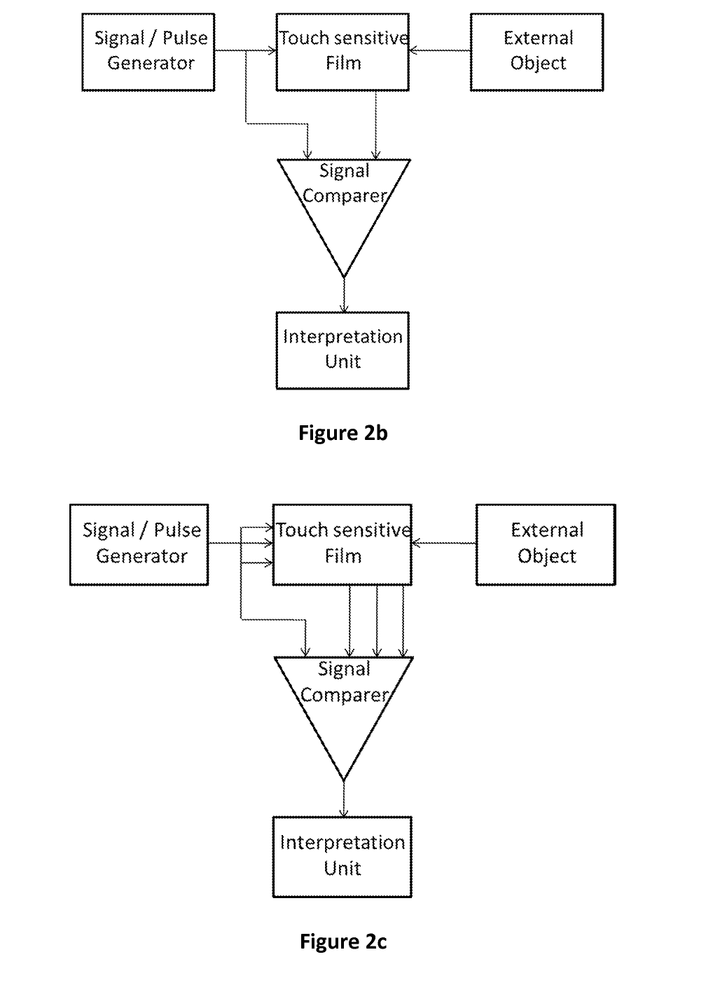

FIG. 2a shows an exemplary embodiment wherein a signal is fed to a node and the effect of the low-pass filter is measured in one or more opposing or adjacent nodes. The system comprises a sensitive film having a resistivity and an external object that capacitively or inductively couples to this sensitive film. The signal or pulse is introduced at a point in the sensitive film, typically at an edge (though it may be introduced anywhere) and the altered signal is received at a different location. The received signal is different depending on the location and capacitance or inductance of the external object and the interaction of the signal with the low-pass filter formed by the touch film and the external object. Using multiple sensing nodes for a single or multiple input nodes permits more exact specification of the location of the touch and the capacitance or inductance of the external object. In the embodiment, to specify x and y location and the capacitance or inductance, 3 input and sensing nodes are needed for each touch, thus, e.g., for 4 simultaneous touches, 12 input and sensing nodes are needed.

A more general configuration of the embodiment according to FIG. 2a is shown on a block diagram of FIG. 2b, and a specific embodiment where three signals or pulses are supplied via three external components to three points (nodes) on the touch film are illustrated on FIG. 2c. The sampled signals or pulses are then compared to the source signal or pulse or to other sampled signals or pulses to determine the location and/or capacitance or inductance of the external object.

In FIGS. 1b, 1c, 2b and 2c the box “signal/pulse generator” represents a generator that produces e.g. one or more excitation voltage or current pulses or oscillations (excitation signals) which can be, for instance, sinusoidal, triangular, square or saw-toothed in form. If needed, it may also include other functionality such as a control unit and/or a clock. The “signal comparer” box indicates a device that compares and differentiates excitation and/or response signals and provides this information to the interpretation unit. It can compare, for instance, voltage or current frequency, amplitude, phase shift, or wave shape or form. The “interpretation unit” box represents a unit that processes the signals out of the signal comparer and possibly also uses information from the signal/pulse generator (e.g. from the clock or control functions). If needed, it may also include other functionality such as a control unit and/or a clock. It may also provide information to, for instance, the signal/pulse generator (e.g. from the clock or control functions). In practice, all these functions may be incorporated in a single unit or chip and thus may be not separate.

The excitation signals can be sent to individual nodes and corresponding samples of the response signal can be taken in sequence, or simultaneously. Furthermore, the same or different excitation signals can be sent to the individual nodes. The excitation signals can be from the same or different sources.

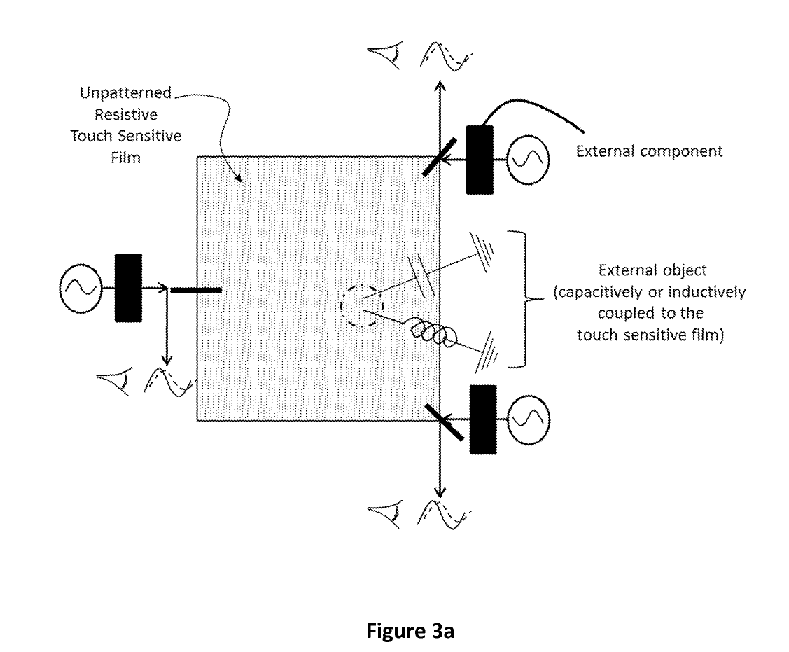

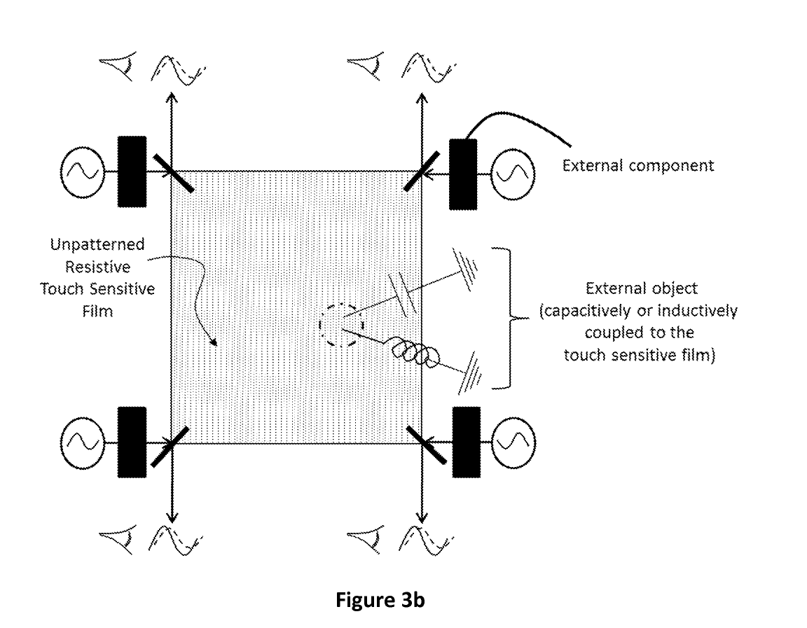

FIG. 3a is an illustration of an embodiment in which a two dimensional touch sensitive film having multiple input signals or pulses (which can be from a single or multiple sources) is used. In this example, three external components are each placed in series between the source and an essentially two dimensional sensitive film, or a sensitive sheet, and the signals are sampled between the external components and the sensitive film. In the case of no touch, the sampled signals will have a given characteristic form in relation to the properties of the filter. When a touch occurs, the capacitive or inductive coupling to the external object changes the filter characteristics. The relationship between the sampled signals, either to each other or to the input signal, provides information on this change of characteristics and therefore on location and capacitance or inductance of the external object. In the embodiment, to specify x and y location and the capacitance or inductance, 3 input and sensing nodes are needed for each touch, thus, e.g., for 4 simultaneous touches, 12 input and sensing nodes are needed. Thus, FIG. 3a shows the minimum number of nodes to fully specify a single touch in terms of location and capacitance or inductance. FIG. 3b shows another embodiment of the same wherein four external components are each placed in series between the source and an essentially two dimensional sensitive film, or a sensitive sheet, and the signals are sampled between the external components and the sensitive film in order to increase accuracy for a single touch or to, e.g., allow for the determination of the presence of multiple touches. The 2-dimensional touch sensitive film described herein may also be flexible and/or formable to a 3D surface.

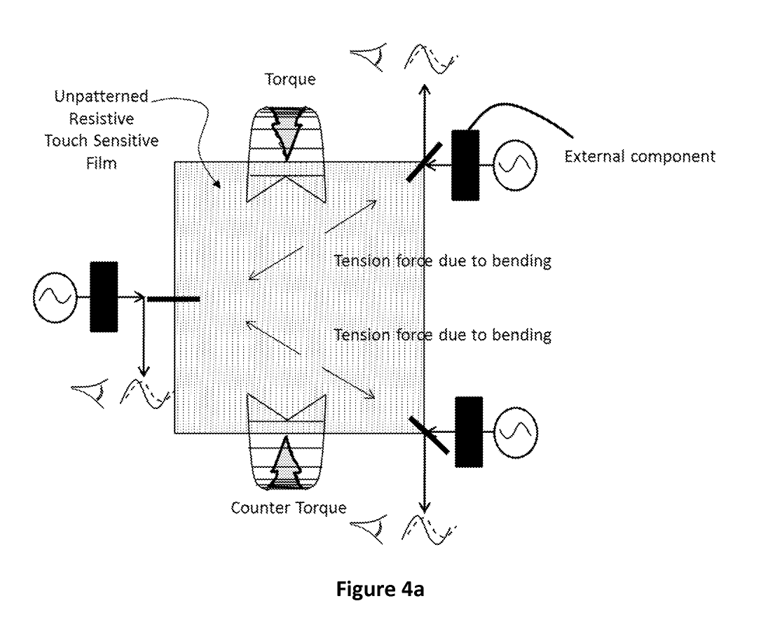

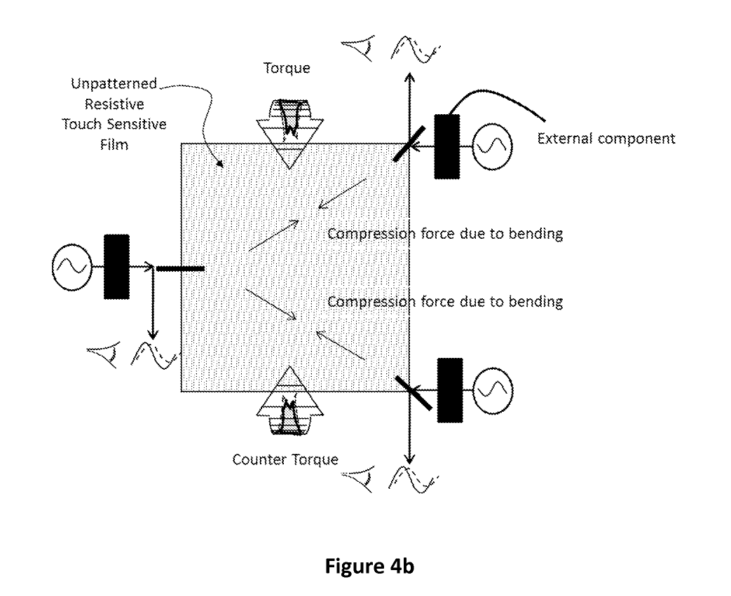

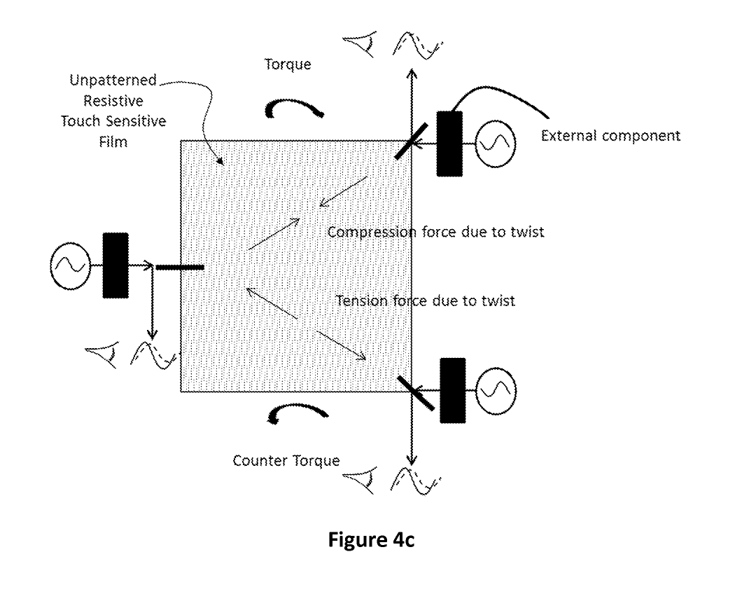

FIGS. 4a-c show examples of sensing film deformation with a single film, in which the sensitive film is alternately coupled to a touch sensing circuitry or algorithm and to a deformation sensing circuitry or algorithm. In this case, at least three nodes are required to perform the measurements. The deformation can be determined by measuring changes in resistance between nodes by a DC voltage level.

In practice, sensor deformation, twisting or bending may impact the touch sensing by changing the active region resistivity that again changes the filter properties. However, in this case the touch sensitive film can still be used at least in a mode wherein the same film serves as a deformation sensor when it is deformed, and as a touch sensor when no deformation is made.

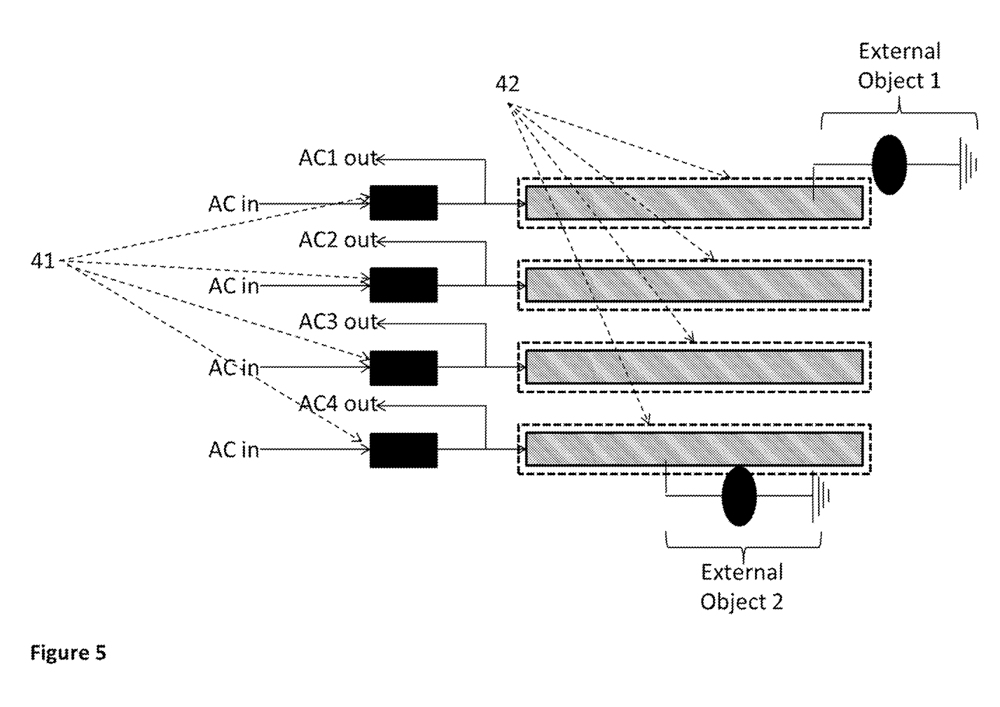

FIG. 5 illustrates an embodiment of a two dimensional touch sensor having multiple input signals or pulses (which can be from a single or multiple sources). An external component 51 is placed in series between the source or sources, and either a single or a set of essentially one dimensional sensing films (a single or collection of sensing fingers or stripes 52) and the signals are sampled between the external components and the sensing films. The stripes should have a high aspect ratio for good performance, e.g. the length to width ratio should be greater than 3, or more preferably, greater than 10. The stripes can be, for instance, straight or curved and need not be of constant width. In the case of a single stripe, the embodiment may act as a slider or dial. In the case of no touch the sampled signals will have a given characteristic forms in relation to the properties of the filter. When a touch occurs, the capacitive or inductive coupling to the external object changes the filter characteristics. The relationship between the sampled signals to the input signal thus provides information on the location of the external object and the existence of a touch in any given strip. To also detect the capacitance or inductance of the external object, one or more additional samples can be taken from the film, preferably at the opposite end of the stripe 52. In the embodiment, to specify a touch location along a stripe, e.g. the x location, and the capacitance or inductance of a touch on said stripe, 2 input and sensing nodes are needed for each touch, thus, e.g., for 4 simultaneous touches along any stripe, 8 input and sensing nodes are needed. This can be operated according to both configurations of FIGS. 1a and 2a. The location of a touch in the essentially orthogonal, e.g. y, direction, is determined by identifying the presence of a touch on a particular stripe.

A modification of this configuration is to fabricate each stripe as “U” or “C” shaped such that, in the case of two electrodes per stripe, the electrodes are located on the same side or edge of the touch region. This can increase the accuracy of the device and allows all the contact electrodes to be localized along one edge, thus allowing design freedom and reducing the need for, e.g. bezels one or more edges of the touch area.

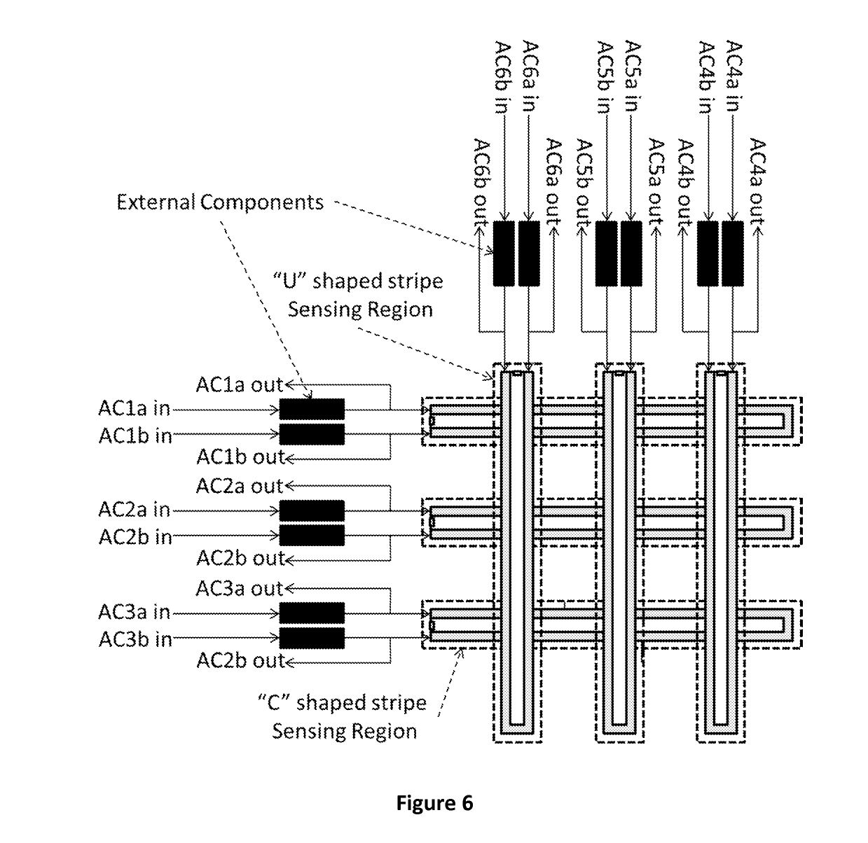

The configuration of FIG. 6 can be used also in a two layer structure, each layer having a set of stripes where the stripes of one layer are oriented so as not to be parallel to the strips of the other layer. Preferably, the orientation is at 90 degrees. In this way a grid structure is formed. FIG. 5 shows this configuration in combination with “U” or “C” shaped stripes. Typically the layers should be separated by, e.g., an air gap or insulating or dielectric material. A substrate or and coating can serve as such an insulator or dielectric.

The markers “AC in” and “AC out” in FIGS. 5 and 6 can mean a signal or pulse input and output, respectively.

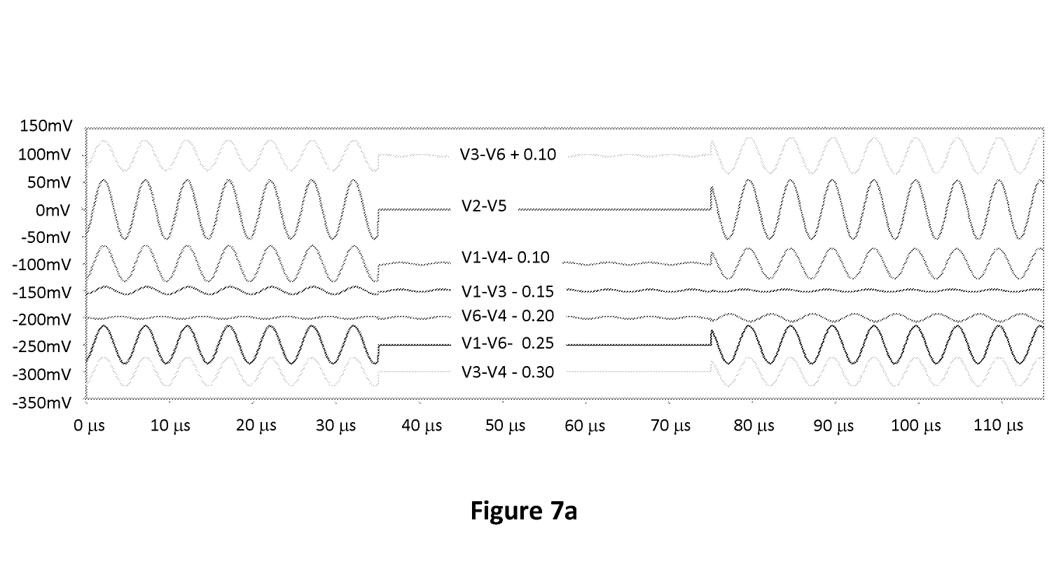

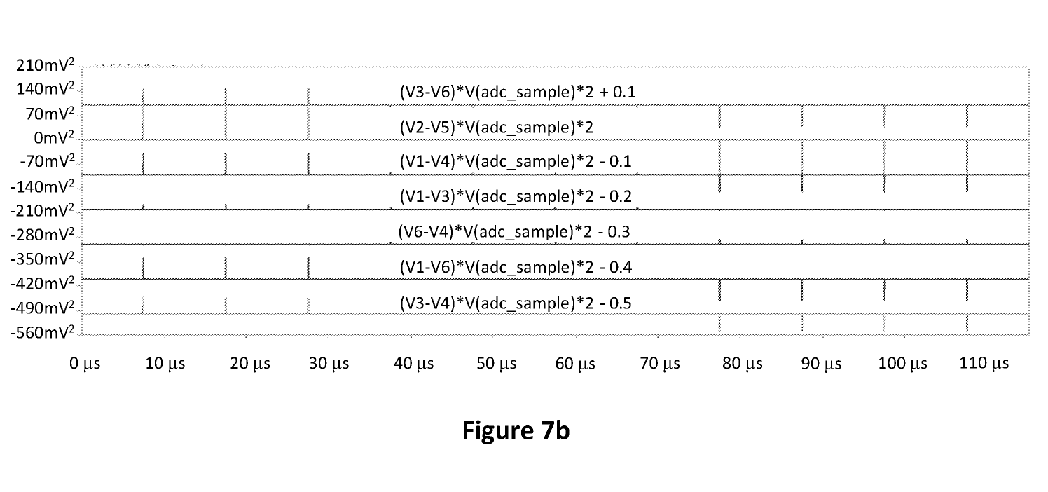

FIG. 7a is a diagram showing a comparison of response signals from a touch on a two-dimensional rectangular touch surface having uniform resistivity and six contact electrodes, two of which are at the centerline edge and opposite each other. The figure shows the difference between response signals between these two contact node when a touch is initially slightly offset to the left from the centerline, then briefly on the centerline but slightly off center toward the top, and then slightly off to right in the end. The graphs show the signal differences between different sensing nodes (receiving electrodes), i.e. the measurements are performed according to the embodiment of claim 4. In the ideal case the difference is zero when the touch is at equal distance and angle from the opposing sensing nodes as is the case for the 2nd and 6th graphs. This clearly shows how the changes in filter properties affect the signal and how e.g. the touch location can be measured.

In FIG. 7b the signals of FIG. 7a are sampled at fixed intervals as would be the case in real system.

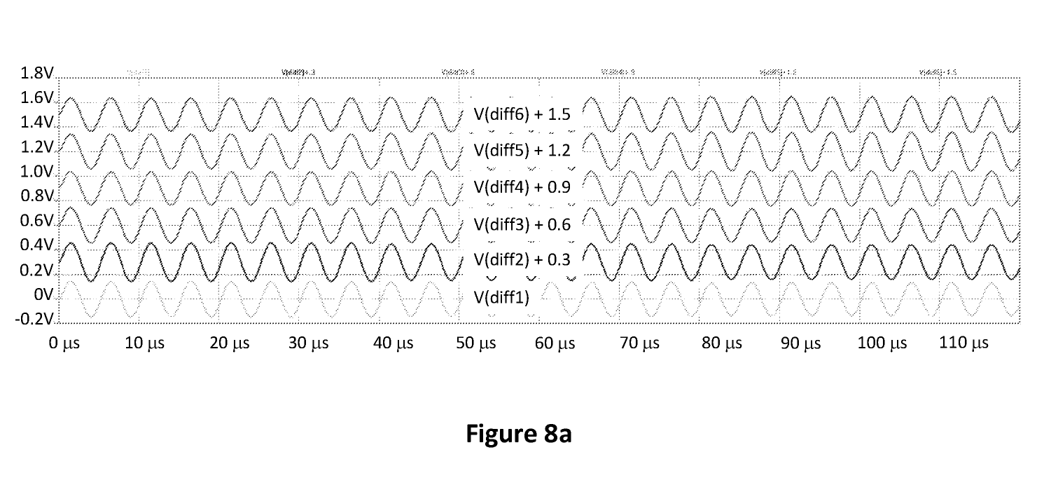

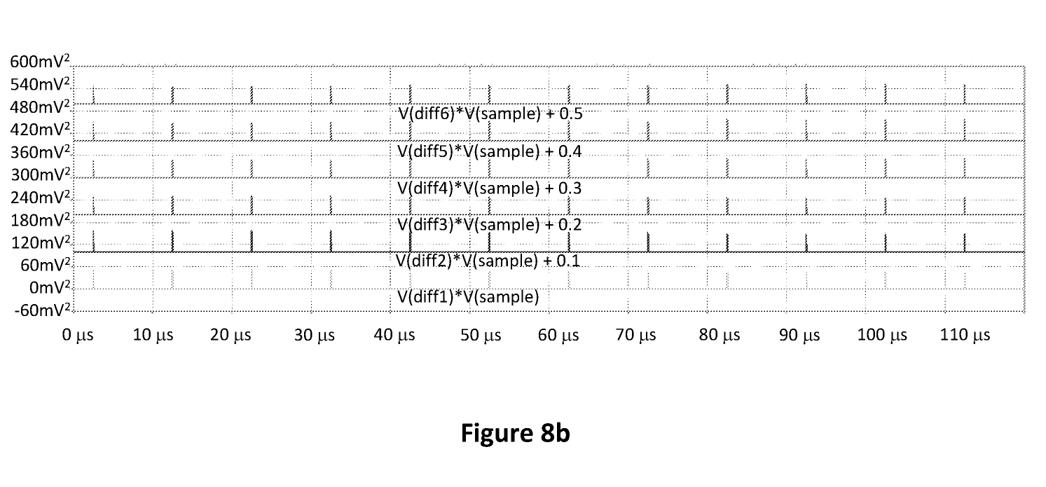

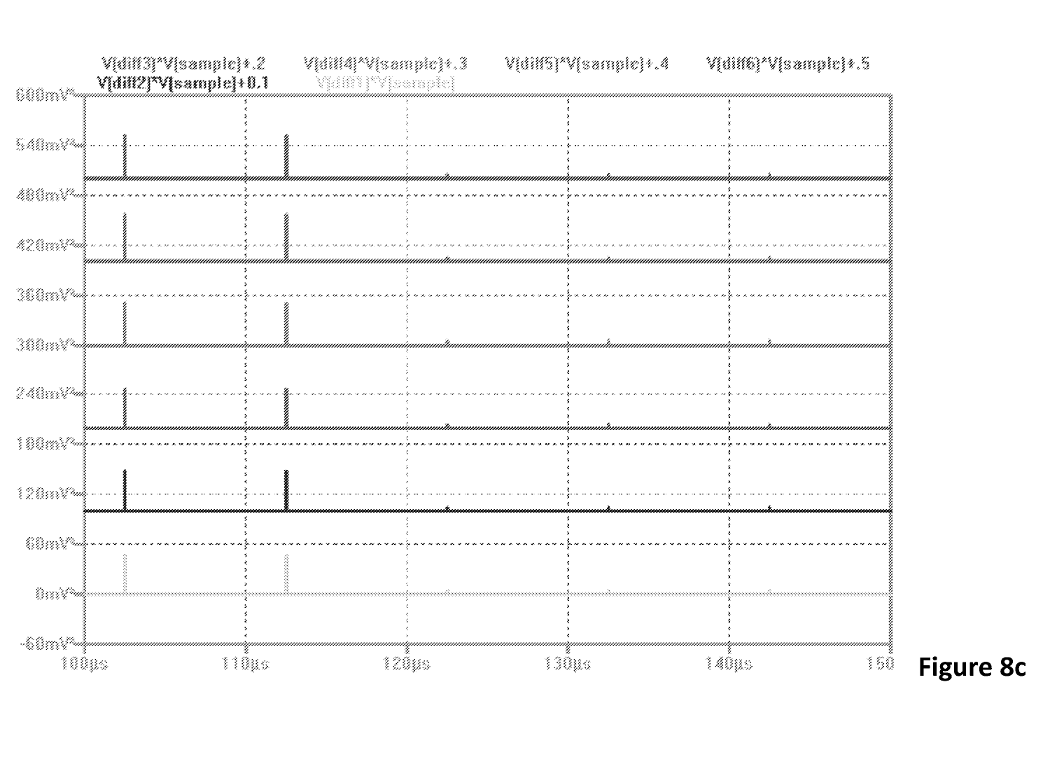

Similarly, as opposed to a difference in response signals at different nodes, the difference between the response signal and the excitation signal can be used to determine changes in the filter properties and thus uniquely determine touch existence, proximity, location and capacitance or inductance of the touch object. FIGS. 8a-c show response signals compared to excitation signals similarly to FIGS. 7a and b. As it is difficult to visually observe the difference in the signals, FIG. 8c displays the response vs. excitation signal difference when the touch is removed at the time position 120 μs.

Other properties of the response signal can also be used to identify changes in the filter properties such as the voltage or current wave form or shape, the amplitude or the phase shift. The property or properties to be sampled and used in the determination of the changes in the filter property can be freely chosen so that, e.g. the signal to noise ratio is maximized. Moreover, the excitation signal frequency, wave shape (e.g. sinusoidal, triangular, square, saw-toothed etc.) and amplitude can be chosen to, for instance, avoid interference or maximize signal to noise ratio.

The invention is not limited to the examples described above but the embodiments can freely vary within the scope of the claims.

1. A touch sensing device, comprising:
a touch sensitive film comprising conductive material having a resistance, the film being capable of capacitive or inductive coupling to an external object when a touch is made by said external object,
a signal filter formed at least by the resistance of the touch sensitive film and the capacitive or inductive coupling to the external object, the signal filter having properties that are affected at least by the location of the touch, the capacitance or inductance of the touch or by a combination of said properties of the touch,
electrical circuitry resistively or wirelessly coupled to the touch sensitive film at one or more locations, the electrical circuitry being configured to supply one or more excitation signals having at least one frequency, amplitude and wave form into the signal filter and to receive one or more response signals from the signal filter, and
a processing unit resistively or wirelessly coupled to the electrical circuitry, wherein the processing unit is configured to detect the presence or proximity of a touch by the external object, the location of said touch, the capacitance or inductance of said touch, or a combination thereof by processing one or more response signals and thereby measuring changes in the properties of the signal filter.

2. The touch sensing device according to claim 1, wherein the signal filter is a low-pass filter.

3. A touch sensing device according to claim 1, wherein the electrical circuitry is configured to receive at least two response signals from the signal filter; and wherein the processing unit is configured to detect the presence of a touch by the external object, the location of said touch, the capacitance or inductance of said touch, or a combination thereof by comparing said response signals to each other and thereby measuring changes in the properties of the signal filter.

4. The touch sensing device according to claim 1, wherein the electrical circuitry is configured to receive at least one response signal from the signal filter; and wherein the processing unit is configured to detect the presence of a touch by the external object, the location of said touch, the capacitance or inductance of said touch, or a combination thereof by comparing said response signals to the source signal and thereby measuring changes in the properties of the signal filter.

5. The touch sensing device according to claim 1, further comprising an external component resistively or wirelessly coupled to the processing unit via the electrical circuitry, wherein the signal filter is further formed by said at least one external component.

6. The touch sensing device according to claim 1, wherein the properties of the signal filter are further affected by the distance between said external object and the sensing film, capacitance or inductance of the external object, physical properties of said external object, the resistance of the film, the existence, thickness or dielectric constant of a dielectric or insulating layer between the sensitive film material and the external object, or by a combination thereof.

7. The touch sensing device according to claim 1, wherein the electrical circuitry comprises one or more electrodes, and wherein at least one of the electrodes is configured to supply said excitation signal into the signal filter, and at least one of the electrodes is configured to receive said electrical response signal from the signal filter.

8. The touch sensing device according to claim 1, wherein the properties of the signal filter include amplitude response, phase response, voltage response, current response, signal shape response or a combination thereof.

9. The touch sensing device according to claim 8, wherein the processing unit is further configured to select one or more properties to be measured based on at least one pre-determined frequency, amplitude and wave form of the excitation signal.

10. The touch sensing device according to claim 1, wherein the touch sensitive film extends as a continuous structure in a plane.

11. The touch sensing device according to claim 1, wherein the touch sensitive film comprises:
two or more parallel stripes made of the conductive material and extending over the touch sensitive film in one direction, and
areas between said stripes comprising non-conducting material,
wherein the electrical circuitry is resistively or wirelessly coupled to each of the stripes, and the processing unit is further configured to detect the presence and location of the touch along each stripe.

12. The touch sensing device according to claim 1, wherein the touch sensitive film is formed as a flexible structure so as to allow bending of the touch sensitive film.

13. The touch sensing device according to claim 1, wherein the touch sensitive film is formed as a deformable structure so as to allow deforming of the touch sensitive film to form a three dimensional surface.

14. The touch sensing device according to claim 1, wherein the touch sensitive film is optically transparent.

15. The touch sensing device according to claim 1, wherein the touch sensitive film comprises a high aspect ratio molecular structure (HARMS) network, a conductive polymer, graphene or a ceramic or metal oxide.

16. The touch sensing device according to claim 1, wherein the touch sensitive film also serves as a haptic interface film.

17. The touch sensing device according to claim 1, wherein the touch sensitive film also serves as a deformation detecting film.

18. The touch sensing device according to claim 1, wherein the capacitance or inductance determined by the processing unit is used as a proxy for determining force or relative change in force of the touch.

19. The touch sensing device according to claim 1, wherein the wireless coupling between parts of said device is one of the following: coupling by radio waves, coupling through magnetic fields, inductive or capacitive coupling.

20. A method for detecting the presence, proximity, location, inductance, capacitance or a combination of these features of an external object with a touch sensing device, the method comprising:
supplying one or more electrical excitation signals having at least one frequency, amplitude and wave form into a signal filter formed at least by a resistance of a touch sensitive film in the touch sensing device and a capacitive or inductive coupling of said film with the external object,
receiving one or more response signals from the signal filter, and
detecting the presence of a touch by the external object, or the location of said touch by processing said one or more response signals and thereby measuring changes in properties of the signal filter.
